(19) United States
(12) Patent Application Publication
(10) Pub. No.: US 2012/0262890 A1
(43) Pub. Date: Oct. 18, 2012

(54) ELECTRONIC DEVICE WITH DEPRESSIBLE AND ROTATABLE WHEEL

(75) Inventors: WEI-RONG XIAO, Shenzhen City (CN); YA-ZHOU LIU, Shenzhen City (CN); CHI TANG, Shenzhen City (CN); PING-CHOU CHEN, Tu-Cheng (TW); HAN-CHE WANG, Tu-Cheng (TW); KUAN-HONG HSIEH, Tu-Cheng (TW)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/284,993

(22) Filed: Oct. 31, 2011

(30) Foreign Application Priority Data
Apr. 18, 2011 (CN) 201110095693.3

(51) Int. Cl. H05K 7/00

(52) U.S. Cl. 361/752; 361/679.01

(57) ABSTRACT

An electronic device includes a housing defining an opening, a circuit board fixed in the housing, a processor, and a wheel module. The wheel module includes a seat, a cantilevered arm, a wheel rotatably fixed to the cantilevered arm and partially extending out of the opening, an encoder fixed to the cantilevered arm, and a micro switch fixed to the seat. One end of the cantilevered arm is fixed to the seat, and an opposite end is free. The cantilevered arm is deformable so as to enable the free end to actuate the micro switch, when the cantilevered arm is depressed. The actuated micro switch then generates a trigger signal. The encoder is configured to convert the rotation of the wheel to corresponding electrical signals, when the wheel is rotated. The processor controls the electronic device to perform preset functions according to the trigger signal or the electrical signals.

### BACKGROUND

1. Technical Field

The present disclosure relates to electronic devices, and particularly, to an electronic device with depressible and rotatable wheel.

2. Description of Related Art

Electronic devices such as digital photo frames, tablet computers, electronic books, mobile phones, and MP3 players can be equipped with physical keys or touch screens to receive user inputs. A user needs to depress different physical keys or touch different areas displaying different icons correspondingly on the touch screen to input, which is inconvenient.

Therefore, what is needed is an electronic device alleviating the limitations described above.

### BRIEF DESCRIPTION OF THE DRAWINGS

The components in the drawings are not necessarily drawn to scale, the emphasis instead being placed upon clearly illustrating the principles of an electronic device with depressible and rotatable wheel. Moreover, in the drawings, like reference numerals designate corresponding parts throughout the several views.

FIG. 1 is an isometric view of an exemplary embodiment of an electronic device with depressible and rotatable wheel.

FIG. 2 is another isometric view of the electronic device of FIG. 1, viewed from another perspective.

FIG. 3 is an exploded view of the electronic device of FIG. 1.

FIG. 4 is an exploded view of the electronic device of FIG. 2.

FIG. 5 is an enlarged, isometric view of the wheel module of the electronic device of FIG. 2.

FIG. 6 is a partial, isometric view of the electronic device of FIG. 1, with the upper cover removed.

### DETAILED DESCRIPTION

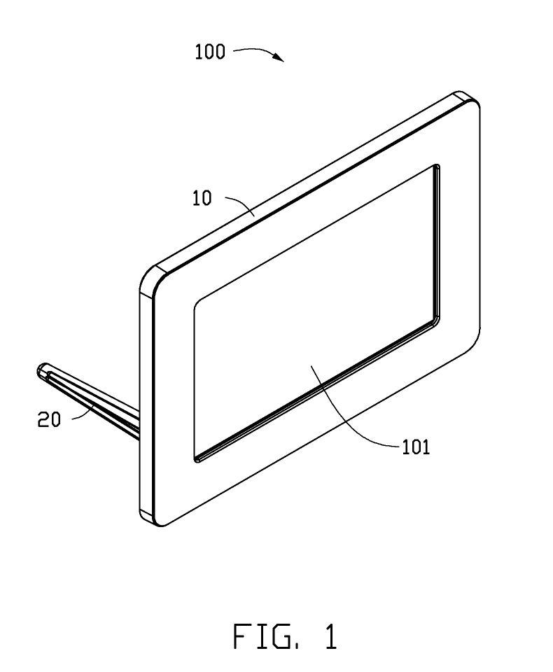

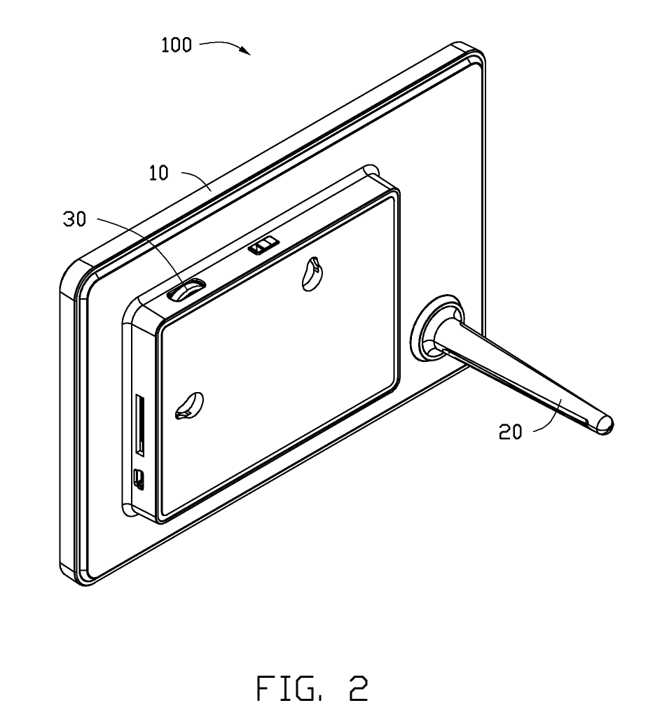

Referring to FIGS. 1 and 2, an electronic device 100 viewed from two different perspectives are disclosed as an exemplary embodiment. The electronic device 100 includes a housing 10 including a screen 101, a support 20 fixed to the housing 10, and a wheel module 30. In the embodiment, a user to control various operations, such as paging up/down, and scrolling, for example, can operate the wheel module 30. The electronic device 100 is a digital photo frame. In an alternative embodiment, the electronic device 100 can be an electronic reader, a tablet computer, or a music player.

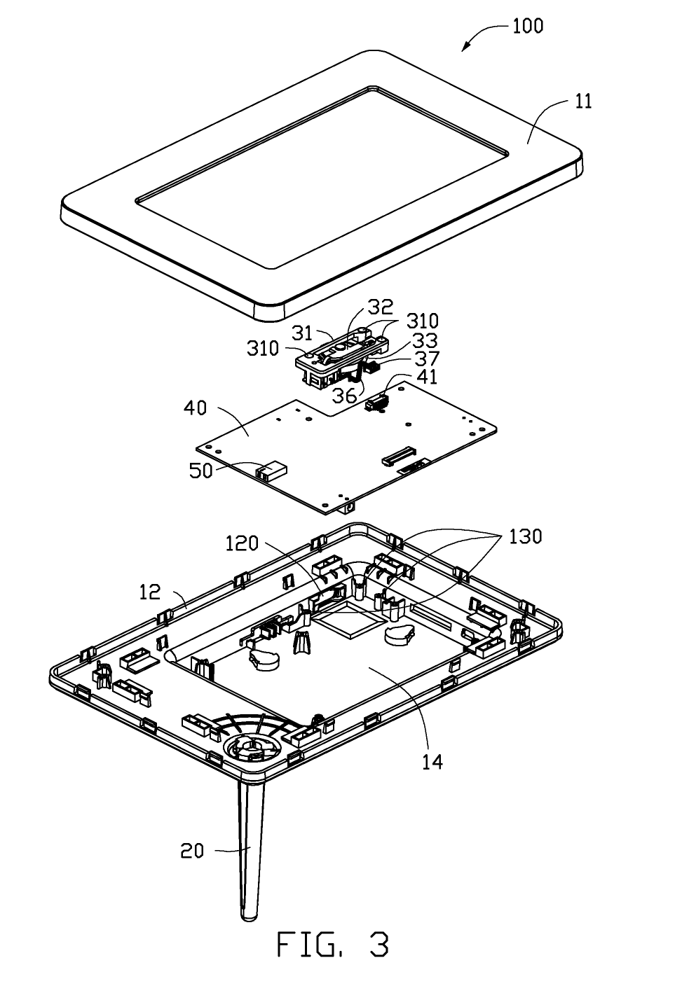

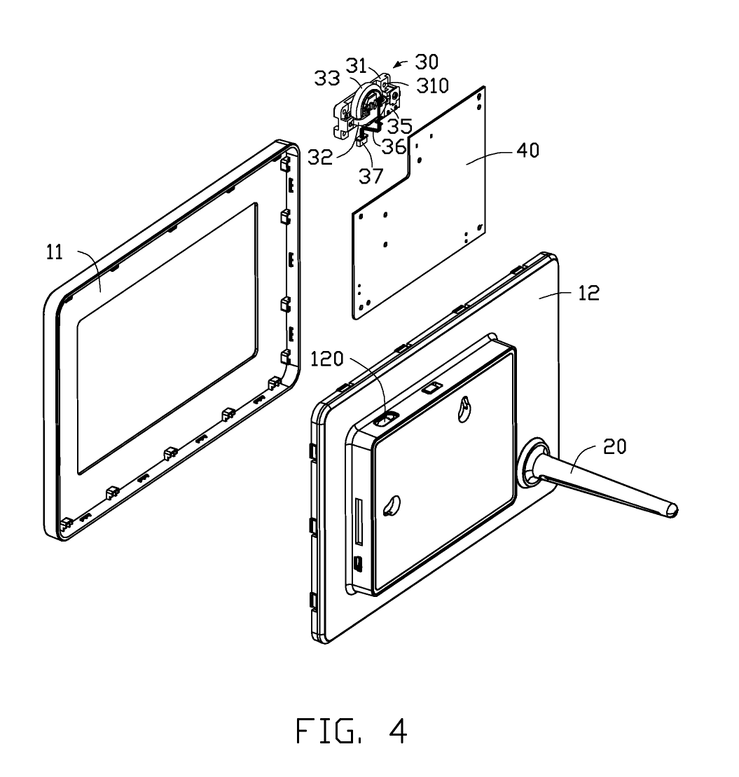

Referring to FIGS. 3 and 4, the housing 10 includes an upper cover 11, a rear cover 12 matching the upper cover 11. The rear cover 12 defines an opening 120 in a sidewall protruding from a bottom 14 and a number of bosses 130 protruding from the bottom 14. In the embodiment, the number of the hollow posts 130 is three.

The electronic device 100 further includes a circuit board 40 fixed to the rear cover 12, and a processor 50 arranged on the circuit board 40. The circuit board 40 includes a connection port 41 receiving operation signals transmitted from the wheel module 30. The processor 50 controls the electronic device 100 to perform preset functions according to the signals transmitted in response to the turning of the wheel module 30.

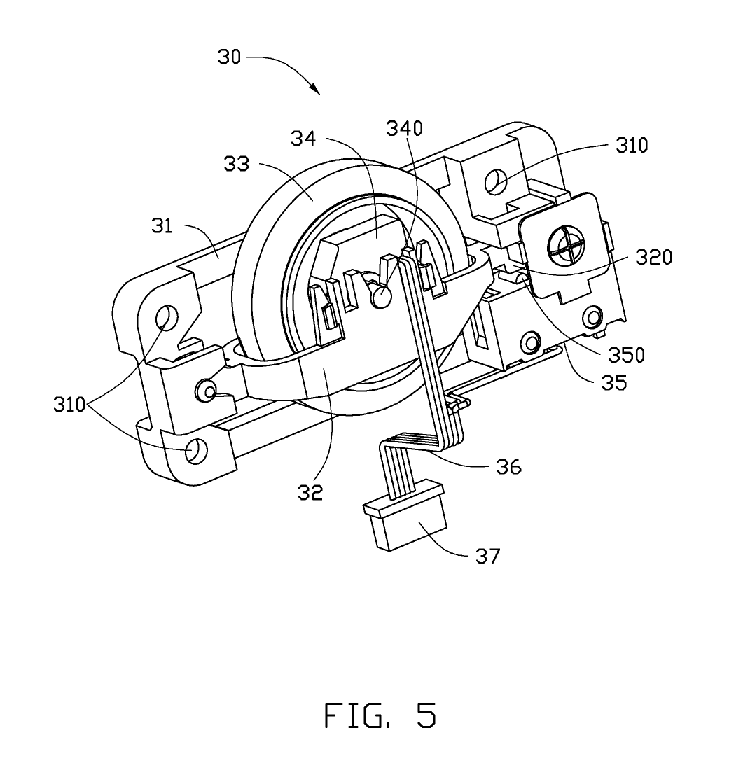

Referring to FIG. 5, the wheel module 30 includes a seat 31, a cantilevered arm 32, a wheel 33, an encoder 34, a micro switch 35 fixed on the seat 31, five data cables 36, and a connector 37 connected to the connection port 41. The seat 31 defines a number of fixing holes 310 corresponding to the bosses 130. One end of the cantilevered arm 32 is fixed to the seat 31, and the other end is a free end including a protrusion 320. The wheel 33 is rotatably connected to the cantilevered arm 32 via a pivot 340 and partially extends out of the opening 120 of the rear cover 12. In the embodiment, the wheel 33 is fixed to the cantilevered arm 32. The encoder 34 is fixed to the cantilevered arm 32 and wheel 33 by the pivot 340. The encoder 34 converts the rotation of the wheel 33 into electrical signals. The micro switch 35 is fixed to the seat 31 and includes a trigger 350 under the protrusion 320. One end of the data cable 36 is connected to the connector 37, and the other, opposite end is connected with the encoder 34 and the micro switch 35.

The electrical signals from the encoder 34 are transmitted to the circuit board 40 via the data cables 36 and the connector 37. When the wheel 33 is depressed, the pressure applied on the wheel 33 is transmitted to the cantilevered arm 32 via the pivot 340. The cantilevered arm 32 then deflects and enables the protrusion 320 on the free end to push the trigger 350 of the micro switch 35, thereby actuating the switch 35. The actuated micro switch 350 then generates a signal, which will be transmitted to the circuit board 40 via the data cables 36 and the connector 37.

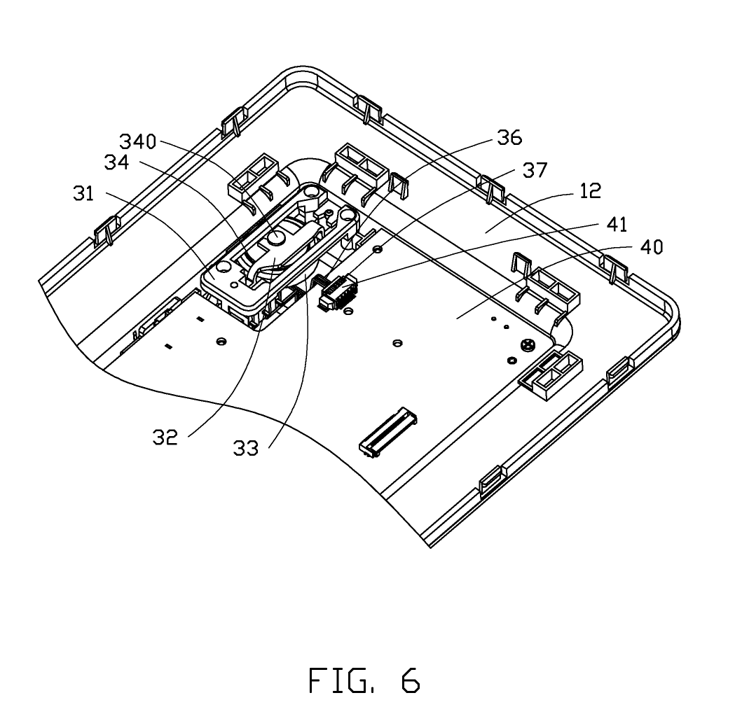

During assembly, the wheel module 30 is first assembled, and the assembled wheel module 30 is then fixed to the rear cover 12 via screws (not shown), and the upper cover 11 is finally connected to the rear cover 12. In the embodiment, the encoder 34 is sleeved on the pivot 340, and the pivot wheel 33 together with the encoder 34 is fixed to the cantilevered arm 32. The cantilevered arm 32 is then fixed to the seat 31. The micro switch 35 is then fixed to the seat 31. Thus, the wheel module 30 is assembled. The wheel module 30 is orientated to align the fixing holes 310 with the bosses 130, and fix the wheel module 30 on the rear cover 12 via screws (not shown) penetrating through the fixing hole 310 and the bosses 130 (See FIG. 6). Finally, the upper cover 11 is connected to the rear cover 12.

In use, the wheel 33 can be rotated or depressed to control operations for the electronic device 100. In the embodiment, the micro switch 35 generates a first signal after the wheel 33 is depressed for a time period longer than a predetermined time period (e.g. 2 seconds), and the processor 50 controls the screen 101 to switch the displayed content to a main menu when the first trigger signal is received. The micro switch 35 generates a second signal after the wheel 33 is depressed for a time period not longer than a predetermined time period (e.g. 2 seconds), and the processor 50 controls the electronic device 100 to perform the preset functions when the second trigger signal is received. The encoder 34 converts the rotation of the wheel 33 to electrical signals when the wheel 33 is rotated clockwise or counterclockwise, and the processor 50 controls the scroll of the displayed page on the screen 101 when the electrical signals are received.

With such a configuration, compared with the common physical keys and virtual keys, the electronic device 100 provides a faster way for flipping photos, displayed pages/contents or other information displayed on the screens via the wheel module 33, which is convenient for users.

Although the present disclosure has been specifically described on the basis of the embodiments thereof, the disclosure is not to be construed as being limited thereto. Various changes or modifications may be made to the embodiments without departing from the scope and spirit of the disclosure.

What is claimed is:

1. An electronic device comprising:
a housing defining an opening;
a processor; and
a wheel module comprising:
a seat;
a cantilevered arm comprising one end fixed to the seat, and an opposite free end;
a wheel rotatably connected to the cantilevered arm and partially extending out of the opening;
an encoder fixed to the cantilevered arm; and
a micro switch fixed to the seat;
wherein the cantilevered arm is deformable so as to enable the free end to actuate the micro switch to generate a trigger signal, when the wheel is depressed, the encoder is configured to convert the rotation of the wheel to electrical signals, when the wheel is rotated, and the processor is configured to control the electronic device to perform preset functions according to the trigger signal or the electrical signals.

2. The electronic device as described in claim 1, wherein the free end of the cantilevered arm comprises a protrusion, and the micro switch comprises a trigger under the protrusion, and the protrusion is configured to push the trigger when the wheel is depressed, thereby actuating the switch.

3. The electronic device as described in claim 1, further comprising a data cable, a connector, and a circuit board fixed to the housing, wherein one end of the data cable is connected to the connector, and an opposite end of the data cable is connected with the encoder and the micro switch, the connector is interconnected between the data cable and the circuit board, and the trigger signals are transmissible to the circuit board via the data cable and the connector.

4. The electronic device as described in claim 1, wherein the electronic device further comprises a screen, the micro switch is configured to generate a first trigger signal after the wheel is depressed for a time period longer than a predetermined time period, and the processor is configured to control the screen to switch the displayed content to a main menu when the first trigger signal is received.

5. The electronic device as described in claim 1, wherein the micro switch is configured to generate a second trigger signal after the wheel is depressed for a time period not longer than a predetermined time period, and the processor is configured to control the electronic device to perform the preset functions when the second trigger signal is received.

6. The electronic device as described in claim 1, wherein the encoder is configured to convert the rotation of the wheel into the electrical signals when the wheel is rotated clockwise or counterclockwise, and the processor is configured to control the scrolling of the displayed page on the screen when the electrical signals are received.

7. The electronic device as described in claim 1, wherein the electronic device is a digital photo frame.
